(19) United States
(12) Patent Application Publication
(10) Pub. No.: US 2025/0085352 A1
(43) Pub. Date: Mar. 13, 2025

(54) APPARATUS AND METHOD FOR ESTIMATION OF BATTERY STATE-OF-CHARGE

(71) Applicant: SAMSUNG SDI CO., LTD., Yongin-si (KR)

(72) Inventor: Sang Min HA, Suwon-si (KR)

(21) Appl. No.: 18/400,057

(22) Filed: Dec. 29, 2023

(30) Foreign Application Priority Data
Sep. 13, 2023 (KR) 10-2023-0121796

(51) Int. Cl. G01R 31/3842; G01R 31/36

(52) U.S. Cl. CPC G01R 31/3842; G01R 31/3648

(57) ABSTRACT

A battery state-of-charge estimation apparatus include: a memory, and a processor connected to the memory. Upon charging/discharging of a battery rack including multiple battery cells, the processor calculates a maximum SOC of a maximum-voltage cell and a minimum SOC of a minimum-voltage cell and calculates a representative SOC of the battery rack based on the maximum SOC and the minimum SOC. A corresponding battery state-of-charge estimation method is also disclosed.

### CROSS-REFERENCE TO RELATED APPLICATION

The present application claims the benefit of Korean Patent Application No. 10-2023-0121796, filed on Sep. 13, 2023, in the Korean Intellectual Property Office, the entire disclosure of which is incorporated herein by reference.

### BACKGROUND

### 1. Field

The present disclosure relates to an apparatus and method for estimation of battery state-of-charge.

### 2. Description of the Related Art

As environmental destruction and resource depletion become serious issues, there is growing interest in energy storage systems (ESS) that can store energy and efficiently utilize the stored energy. An ESS includes dozens to hundreds of cells connected in series or parallel to form a battery rack.

As a method of controlling charging/discharging of multiple cells constituting such a battery rack, an average SOC (stage of charge) of the multiple cells in the battery rack is calculated to perform charging/discharging of the cells based on the calculated average of SOC.

However, there is a problem of deviation in states of charge of the cells if the state of charge of each cell is determined based on the average SOC of the multiple cells in the battery rack upon charging/discharging the cells.

### SUMMARY

Embodiments include a battery state-of-charge estimation apparatus. The apparatus includes a memory; and a processor connected to the memory. Upon charging/discharging a battery rack comprising multiple battery cells, the processor calculates a maximum state of charge (SOC) of a maximum-voltage cell and a minimum SOC of a minimum-voltage cell and calculates a representative SOC of the battery rack based on the maximum SOC and the minimum SOC.

The battery state-of-charge estimation apparatus, wherein, upon charging/discharging the battery rack, the processor may calculate the maximum SOC based on a voltage and current of the maximum-voltage cell having a highest voltage among voltages of the multiple battery cells, and calculates the minimum SOC based on a voltage and current of the minimum-voltage cell having a lowest voltage among the voltages of the multiple battery cells.

The battery state-of-charge estimation apparatus, wherein the processor may calculate a first weight of the maximum SOC and a second weight of the minimum SOC based on a battery operation range, an average SOC and a deviation SOC of the maximum SOC and the minimum SOC, and may apply the first weight and the second weight to the maximum SOC and the minimum SOC, respectively, to calculate the representative SOC.

The battery state-of-charge estimation apparatus, wherein the processor may apply the deviation SOC to a first SOC upper limit and a first SOC lower limit corresponding to the battery operation range to calculate a second SOC upper limit and a second SOC lower limit, and may calculate the first weight of the maximum SOC and the second weight of the minimum SOC based on the second SOC upper limit, the second SOC lower limit, and the average SOC.

The battery state-of-charge estimation apparatus, wherein the processor may subtract a preset ratio of the deviation SOC from the first SOC upper limit to calculate the second SOC upper limit and may add the preset ratio of the deviation SOC to the first SOC lower limit to calculate the second SOC lower limit.

The battery state-of-charge estimation apparatus, wherein the processor may calculate the second weight by dividing a value obtained through subtraction of the average SOC from the second SOC upper limit by a value obtained through subtraction of the second SOC lower limit from the second SOC upper limit, and may calculate the first weight by subtracting the second weight from 1.

Embodiments include a battery state-of-charge estimation method. The method includes, upon charging/discharging a battery rack comprising multiple battery cells, receiving, by a processor, measurement data of each of the battery cells from a sensor, calculating, by the processor, a maximum SOC of a maximum-voltage cell and a minimum SOC of a minimum-voltage cell based on the measurement data of each of the battery cells, and calculating, by the processor, a representative SOC of the battery rack based on the maximum SOC and the minimum SOC.

The battery state-of-charge estimation method, wherein, in calculating the maximum SOC of the maximum-voltage cell and the minimum SOC of the minimum-voltage cell, the processor may calculate the maximum SOC based on a voltage and current of the maximum-voltage cell having a highest voltage among voltages of the multiple battery cells, and the minimum SOC based on a voltage and current of the minimum-voltage cell having a lowest voltage among the voltages of the multiple battery cells.

The battery state-of-charge estimation method, wherein calculating a representative SOC of the battery rack may include calculating, by the processor, an average SOC and a deviation SOC of the maximum SOC and the minimum SOC, applying, by the processor, the deviation SOC to a first SOC upper limit and a first SOC lower limit corresponding to a battery operating range to calculate a second SOC upper limit and a second SOC lower limit, calculating, by the processor, a first weight of the maximum SOC and a second weight of the minimum SOC based on the second SOC upper limit, the second SOC lower limit, and the average SOC, and applying, by the processor, the first weight and the second weight to the maximum SOC and the minimum SOC, respectively, to calculate the representative SOC of the battery rack.

The battery state-of-charge estimation method, wherein, in calculating the second SOC lower limit, the processor may subtract a preset ratio of the deviation SOC from the first SOC upper limit to calculate the second SOC upper limit and may add the preset ratio of the deviation SOC to the first SOC lower limit to calculate the second SOC lower limit.

The battery state-of-charge estimation method, wherein, in calculating the second weight, the processor may divide a value obtained through subtraction of the average SOC from the second SOC upper limit by a value obtained through subtraction of the second SOC lower limit from the second SOC upper limit and calculates the first weight by subtracting the second weight from 1.

### BRIEF DESCRIPTION OF DRAWINGS

Features will become apparent to those of skill in the art by describing in detail exemplary embodiments with reference to the attached drawings in which:

FIG. 1 is a schematic block diagram of a battery state-of-charge estimation system according to one embodiment.

FIG. 2 is a schematic block diagram of a battery state-of-charge estimation apparatus according to one embodiment.

FIG. 3 is a flow diagram illustrating a method for calculating a representative SOC of a battery rack according to one embodiment.

FIG. 4 is a graph comparing the representative SOC calculation method according to the embodiment with a typical SOC calculation method.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that where a layer or element is referred to as being “on” another layer or substrate, it can be directly on the other layer or substrate, or intervening layers may also be present. Further, it will be understood that where a layer is referred to as being “under” another layer, it can be directly under, and one or more intervening layers may also be present. It will also be understood that where a layer is referred to as being “between” two layers, it can be the only layer between the two layers, or one or more intervening layers may also be present. Like reference numerals refer to like elements throughout.

It will be understood that if an element or layer is referred to as being “on,” “connected to,” or “coupled to” another element or layer, it may be directly on, connected, or coupled to the other element or layer or one or more intervening elements or layers may also be present. If an element or layer is referred to as being “directly on,” “directly connected to,” or “directly coupled to” another element or layer, there are no intervening elements or layers present. In an example embodiment, if a first element is described as being “coupled” or “connected” to a second element, the first element may be directly coupled or connected to the second element or the first element may be indirectly coupled or connected to the second element via one or more intervening elements.

As used herein, the term “and/or” includes any and all combinations of one or more of the associated listed items. Further, the use of “may” where describing embodiments of the present disclosure relates to “one or more embodiments of the present disclosure.” Expressions, such as “at least one of” and “any one of,” where preceding a list of elements, modify the entire list of elements and do not modify the individual elements of the list. If phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first and second, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation to the orientation depicted in the figures. In an implementation, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the singular forms “a” and “an” are intended to include the plural forms as well, unless the context clearly indicates otherwise. It will be further understood that the terms “includes,” “including,” “comprises,” and/or “comprising,” if used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, i.e., having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Thus, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Throughout the specification, unless otherwise stated, each element may be singular or plural.

It will be understood that where an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In some embodiments, if a part is referred to as being “electrically coupled” to another part, the part can be directly connected to another part or an intervening part may be present therebetween such that the part and another part are indirectly connected to each other.

Throughout the specification, if “A and/or B” is stated, it means A, B or A and B, unless otherwise stated. In embodiments, “and/or” includes any or all combinations of a plurality of items enumerated. If “C to D” is stated, it means C or more and D or less, unless otherwise specified.

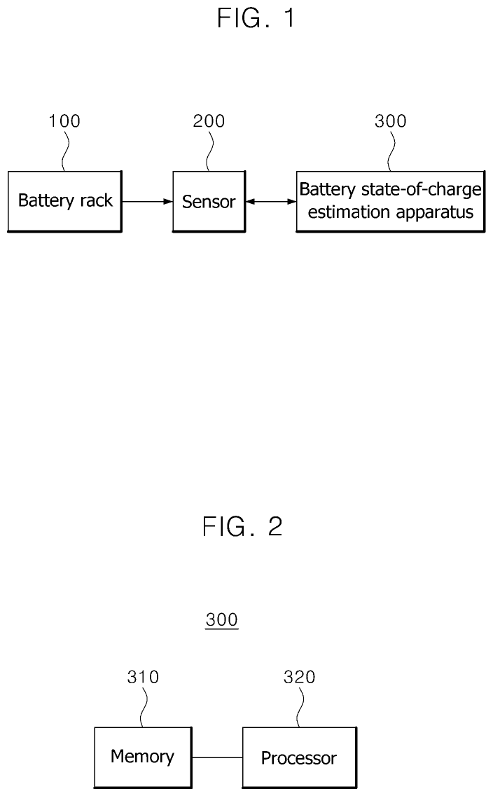

FIG. 1 is a schematic block diagram of a battery state-of-charge estimation system according to one embodiment.

Referring to FIG. 1, a battery state-of-charge (SOC) estimation system according to one embodiment includes a battery rack 100, a sensor 200, and a battery state-of-charge estimation apparatus 300.

The battery rack 100 may include multiple battery cells arranged in series to form a single package. The battery rack 100 may include first to n^{th} battery cells arranged in series. Although this embodiment will be described with multiple battery cells connected to each other in series, embodiments may be applied to battery cells connected in series and/or in parallel.

The battery cells may include lithium-ion cells, lithium polymer cells, nickel-cadmium cells, nickel-hydrogen cells, nickel-zinc cells, and the like, which can be repeatedly charged and discharged.

While the multiple cells constituting the battery rack 100 are charged/discharged, the sensor 200 may measure a current and voltage of each of the cells at predetermined periodic intervals and may transmit the measured data of each of the cells to the battery state-of-charge estimation apparatus 300. The measurement data may include the current, voltage, and the like of each cell.

Such a sensor 200 may include a voltage sensor and a current sensor to measure voltage and current of each cell and may measure the current and voltage of each cell under charging/discharging conditions at predetermined periodic intervals.

The battery state-of-charge estimation apparatus 300 may calculate a representative SOC of the battery rack 100 based on the measurement data of each of the cells measured by the sensor 200. The representative SOC of the battery rack 100 may be a parameter indicative of the state of charge of the battery rack 100 and may be a value representative of the SOC of the battery rack 100 including the cells.

The battery state-of-charge estimation apparatus 300 is a device for estimating the state of a battery and may be realized by a software module, a hardware module, or a combination thereof. In an example embodiment, the battery state-of-charge estimation apparatus 300 may be realized by a battery management system (BMS). The BMS is a system that manages batteries, in embodiments, by monitoring conditions of the batteries, maintaining optimized conditions under which the batteries operate, predicting when the batteries are required to replaced, detecting problems with the batteries, and generating control or instruction signals associated with the batteries to control the condition or operation of the batteries.

The battery state-of-charge estimation apparatus 300 will be described in detail with reference to FIG. 2.

FIG. 2 is a schematic block diagram of a battery state-of-charge estimation apparatus according to one embodiment.

Referring to FIG. 2, the battery state-of-charge estimation apparatus 300 according to one or more embodiments may include a memory 310 and a processor 320.

The memory 310 stores data related to operation of the battery state-of-charge estimation apparatus 300. In some embodiments, the memory 310 may store an application (program or applet) or the like, which calculates a maximum SOC of a maximum-voltage cell and a minimum SOC of a minimum-voltage cell and calculates a representative SOC of the battery rack 100 based on the maximum SOC and the minimum SOC upon charging/discharging a battery rack 100 including multiple cells, in which data stored in the memory 310 may be selected by processor 320 as needed. In embodiments, the memory 310 stores various types of data generated during execution of an operating system or a control application (program or applet) for operation of the battery state-of-charge estimation apparatus 300. In some embodiments, the memory 310 may store a first SOC upper limit and a first SOC lower limit corresponding to a battery operation range, measurement data of each cell, and the like. Such a memory 310 may include magnetic storage media or flash storage media in addition to volatile storage devices that require power to maintain the stored data, without being limited thereto.

Upon charging/discharging (i.e., charging or discharging) the battery rack 100 including the multiple cells, the processor 320 may calculate the maximum SOC of the maximum-voltage cell and the minimum SOC of the minimum-voltage cell, and may calculate the representative SOC of the battery rack 100 based on the maximum SOC and the minimum SOC.

Hereinafter, operation of the processor 320 will be described in detail.

The processor 320 may receive measurement data of each cell from the sensor 200 at regular intervals while the multiple cells included in the battery rack 100 are simultaneously charged/discharged. In this example implementation, the measurement data may include voltage and current of each cell.

Where the measurement data of each cell is received, the processor 320 may calculate the maximum SOC of the maximum-voltage cell and the minimum SOC of the minimum-voltage cell. In this example implementation, the processor 320 may calculate the maximum SOC based on a voltage and current of the maximum-voltage cell having the highest voltage among voltages of the multiple cells. Further, the processor 320 may calculate the minimum SOC based on a voltage and current of the minimum-voltage cell having the lowest voltage among the voltages of the multiple cells. SOC is a parameter indicative of the state of charge and indicates how much energy is stored in a given cell, and SOC may be expressed as a quantity from 0% to 100%. In an implementation, 0% may mean a fully discharged state and 100% may mean a fully charged state. However, it should be noted that this representation may be defined in various variations depending on a design intention or an embodiment.

Once the maximum SOC and the minimum SOC are calculated, the processor 320 may calculate an average SOC and a deviation SOC of the maximum SOC and the minimum SOC. In this example implementation, the processor 320 may calculate the average SOC according to Equation 1 below and the deviation SOC according to Equation 2.

$$Average SOC = ( Maximum SOC + Minimum SOC ) / 2 \qquad [ Equation 1 ]$$

$$Deviation SOC = Maximum SOC - Minimum SOC \qquad [ Equation 2 ]$$

Then, the processor 320 may apply the deviation SOC to the first SOC upper limit and the first SOC lower limit, which correspond to the battery operation range, to calculate a second SOC upper limit and a second SOC lower limit. In this example implementation, the first SOC upper limit and the first SOC lower limit corresponding to the battery operation range may refer to a preset operating limit range. The processor 320 may calculate the second SOC upper limit by subtracting a preset ratio of the deviation SOC from the first SOC upper limit and may calculate the second SOC lower limit by adding the preset ratio of the deviation SOC to the first SOC lower limit. In an example embodiment, the processor 320 may subtract or add ½ of the deviation SOC with respect to the first SOC upper limit and the first SOC lower limit, which correspond to the battery operation range, to calculate the second SOC upper limit and the second SOC lower limit. In some embodiments, the processor 320 may calculate the second SOC upper limit and the second SOC lower limit according to Equations 3 and 4, respectively.

$$Second SOC upper limit = First SOC upper limit - ( deviation SOC / 2 ) \qquad [ Equation 3 ]$$

$$Second SOC lower limit = First SOC lower limit + ( deviation SOC / 2 ) \qquad [ Equation 4 ]$$

Once the second SOC upper limit and the second SOC lower limit are calculated, the processor 320 may calculate a first weight of the maximum SOC and a second weight of the minimum SOC based on the second SOC upper limit, the second SOC lower limit, and the average SOC, respectively. In this example implementation, the processor 320 may subtract the average SOC from the second SOC upper limit and the second SOC lower limit to calculate the second weight of the minimum SOC and the first weight of the maximum SOC, respectively. In some embodiments, the processor 320 may calculate the second weight and the first weight according to Equations 5 and 6, respectively.

$$Secondary weight = ( Second SOC upper limit - Average SOC ) / ( Second SOC upper limit - Second SOC lo wer limit ) \qquad [ Equation 5 ]$$

$$First weight = 1 - Second weight \qquad [ Equation 6 ]$$

Once the first weight and the second weight are calculated, the processor 320 may apply the first weight and the second weight to the maximum SOC and the minimum SOC to calculate a representative SOC of the battery rack 100. In this example implementation, the processor 320 may calculate the representative SOC of the battery rack 100 according to Equation 7.

$$[ Equation 7 ]$$

$$Representative SOC = First weight ⋆ maximum SOC + Second weight ⋆ minimum SOC$$

Such a processor 320 has a configuration that controls the overall operation of the battery state-of-charge estimation apparatus 300 and may be realized by, in example embodiments, an integrated circuit, a system-on-chip, or a mobile AP.

The processor 320 may control the overall operation of the battery state-of-charge estimation apparatus 300. The processor 320 may refer to a data processing device embedded in hardware and having, in an example implementation, a physically structured circuit to perform functions expressed by code or instructions contained within a program. Examples of the hardware-embedded data processing device may include a microprocessor, a central processing unit (CPU), a processor core, a multiprocessor, an application-specific integrated circuit (ASIC), a field programmable gate array (FPGA), and the like, without being limited thereto.

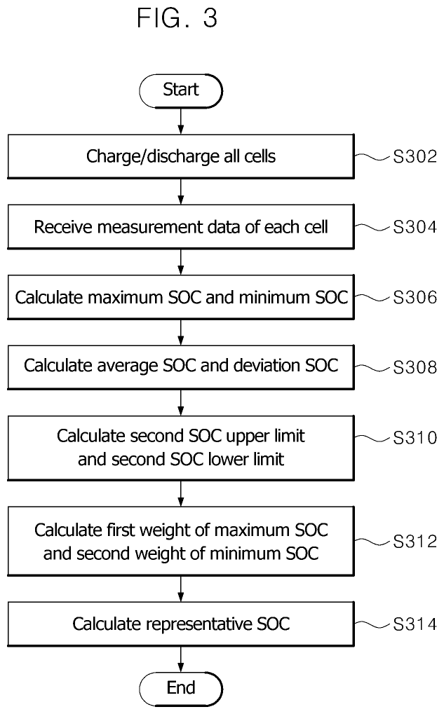

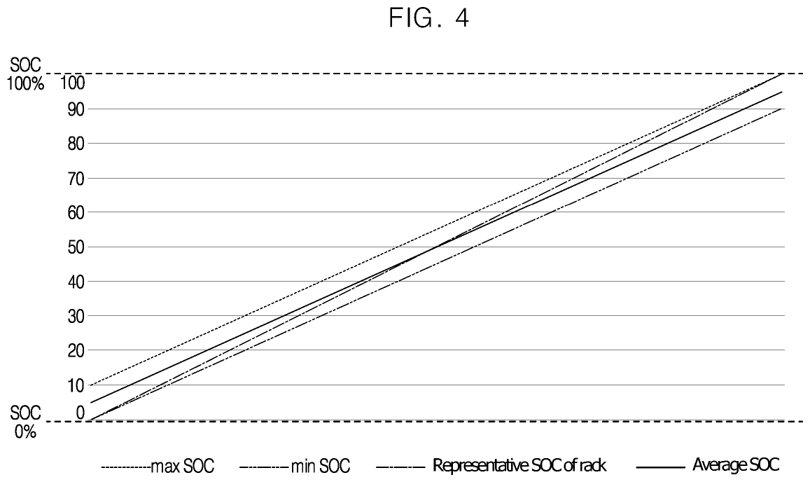

FIG. 3 is a flow diagram illustrating a method of calculating a representative SOC of a battery rack according to one embodiment and FIG. 4 is a diagram comparing the representative SOC calculation method according to the embodiment with a comparative SOC calculation method.

Referring to FIG. 3, while multiple cells included in a battery rack 100 are simultaneously charged/discharged (S302), the processor 320 receives measurement data of each cell from the sensor 200 at regular intervals (S304). The measurement data may include a voltage and current of each cell.

After step S304 is performed, the processor 320 may calculate a maximum SOC of a maximum-voltage cell and a minimum SOC of a minimum-voltage cell based on the measurement data of each cell (S306). In this example implementation, the processor 320 may calculate the maximum SOC based on a voltage and current of the maximum-voltage cell having the highest voltage among voltages of the multiple cells. Further, the processor 320 may calculate the minimum SOC based on a voltage and current of the minimum-voltage cell having the lowest voltage among the voltages of the multiple cells.

After step S306 is performed, the processor 320 may calculate an average SOC and a deviation SOC of the maximum SOC and the minimum SOC (S308). In this example implementation, the processor 320 may calculate an average of the maximum SOC and the minimum SOC as the average SOC. Further, the processor 320 may calculate a difference between the maximum SOC and the minimum SOC as the deviation SOC.

After step S308 is performed, the processor 320 may apply the deviation SOC to a first SOC upper limit and a first SOC lower limit, which correspond to a battery operation range, to calculate a second SOC upper limit and a second SOC lower limit (S310). In this example implementation, the processor 320 may subtract ½ of the deviation SOC from the first SOC upper limit, which corresponds to the battery operation range, to calculate the second SOC upper limit. Further, the processor 320 may add ½ of the deviation SOC to the first SOC lower limit, which corresponds to the battery operation range, to calculate the second SOC lower limit.

After step S310 is performed, the processor 320 may calculate a first weight of the maximum SOC and a second weight of the minimum SOC based on the second SOC upper limit, the second SOC lower limit, and the average SOC, respectively (S312). In this example implementation, the processor 320 may calculate the second weight by dividing a value obtained through subtraction of the average SOC from the second SOC upper limit by a value obtained through subtraction of the second SOC lower limit from the second SOC upper limit. Further, the processor 320 may calculate the first weight by subtracting the second weight from 1.

After step S312 is performed, the processor 320 applies the first weight and the second weight to the maximum SOC and the minimum SOC, respectively, to calculate a representative SOC of the battery rack 100 (S314). In this example implementation, the processor 320 may calculate the representative SOC by adding a value obtained by multiplying the maximum SOC by the first weight to a value obtained by multiplying the minimum SOC by the second weight.

In some embodiments, the first SOC upper limit may be 100%, the first SOC lower limit is 0%, the maximum SOC of the maximum-voltage cell is 90%, and the minimum SOC of the minimum-voltage cell may be 70%, the representative SOC may be calculated by the following method.

First, the processor 320 may calculate an average SOC 80%, which is an average of the maximum SOC 90% and the minimum SOC 70%, and a deviation SOC 20%, which is a difference between the maximum SOC 90% and the minimum SOC 70%.

Then, the processor 320 may subtract ½ of the deviation SOC 20% from the first SOC upper limit 100% (100%−(20%/2)) to obtain a second upper limit 90% and may add ½ of the deviation SOC 20% to the first SOC lower limit 0% (0%+(20%/2)) to obtain a second lower limit 10%.

Then, the processor 320 may calculate (second SOC upper limit 90%−average SOC 80%)/(second SOC upper limit 90%−second SOC lower limit 10%)=0.125 as the second weight, and (1−second weight 0.125)=0.875 as the first weight.

Next, the processor 320 may calculate ((first weight 0.875*maximum SOC 90%)+(second weight 0.125*minimum SOC 70%))=87.5% as the representative SOC.

As described above, the apparatus and method according to an embodiment can protect batteries from a risk of overcharging/overdischarging by calculating a representative SOC of the battery rack 100 based on the maximum SOC of the highest voltage cell and the minimum SOC of the lowest voltage cell upon charging/discharging the battery rack 100 including multiple cells. In an example embodiment, referring to FIG. 4, at the time of a full charge (SOC 100%), the representative SOC of the battery rack 100 is 100% and there is no risk of overcharging. However, if the SOC is calculated based on an average voltage of all cells at the time of full charge (SOC 100%), there is a risk of overcharging the battery rack to an SOC of 105%.

If the SOC is calculated from an average voltage of all cells, there is also a risk of overcharging at the time of full charge and overdischarging at the time of full discharge due to an error from an available capacity of an actual battery rack. In an implementation, cells having a higher SOC than an average SOC can be charged (overcharged) more than necessary and cells having a lower SOC than the average SOC can be discharged (overdischarged) more than necessary, and some cells continue to charge/discharge intermittently at upper and lower limits of the depth of discharge (DOD). This phenomenon acts a major factor of cell degeneration and results in degradation in battery performance.

Embodiments include an apparatus and method for estimation of battery state-of-charge for protecting batteries from overcharging/overdischarging in a battery rack including multiple cells.

In accordance with one or more embodiments, a battery state-of-charge estimation may include: a memory; and a processor connected to the memory, wherein, upon charging/discharging of a battery rack including multiple cells, the processor calculates a maximum state of charge (SOC) of a maximum-voltage cell and a minimum SOC of a minimum-voltage cell and calculates a representative SOC of the battery rack based on the maximum SOC and the minimum SOC.

In some embodiments, upon charging/discharging the battery rack, the processor may calculate the maximum SOC based on a voltage and current of the maximum-voltage cell having the highest voltage among voltages of the multiple cells, and may calculate the minimum SOC based on a voltage and current of the minimum-voltage cell having the lowest voltage among the voltages of the multiple cells.

In some embodiments, the processor may calculate a first weight of the maximum SOC and a second weight of the minimum SOC based on a battery operation range, an average SOC and a deviation SOC of the maximum SOC and the minimum SOC, and may apply the first weight and the second weight to the maximum SOC and the minimum SOC to calculate the representative SOC, respectively.

In some embodiments, the processor may apply the deviation SOC to a first SOC upper limit and a first SOC lower limit corresponding to the battery operation range to calculate a second SOC upper limit and a second SOC lower limit, and may calculate the first weight of the maximum SOC and the second weight of the minimum SOC based on the second SOC upper limit, the second SOC lower limit, and the average SOC.

In some embodiments, the processor may subtract a preset ratio of the deviation SOC from the first SOC upper limit to calculate the second SOC upper limit and may add the preset ratio of the deviation SOC to the first SOC lower limit to calculate the second SOC lower limit.

In some embodiments, the processor may calculate the second weight by dividing a value obtained through subtraction of the average SOC from the second SOC upper limit by a value obtained through subtraction of the second SOC lower limit from the second SOC upper limit and may calculate the first weight by subtracting the second weight from 1.

In embodiments, a battery state-of-charge estimation method may include, upon charging/discharging a battery rack including multiple cells, receiving, by a processor, measurement data of each of the cells from a sensor, calculating, by the processor, a maximum SOC of a maximum-voltage cell and a minimum SOC of a minimum-voltage cell based on the measurement data of each of the cells; and calculating, by the processor, a representative SOC of the battery rack based on the maximum SOC and the minimum SOC.

In some embodiments, in calculation of the maximum SOC of the maximum-voltage cell and the minimum SOC of the minimum-voltage cell, the processor may calculate the maximum SOC based on a voltage and current of the maximum-voltage cell having the highest voltage among voltages of the multiple cells, and may calculate the minimum SOC based on a voltage and current of the minimum-voltage cell having the lowest voltage among the voltages of the multiple cells.

In some embodiments, the step of calculating a representative SOC of the battery rack may include calculating, by the processor, an average SOC and a deviation SOC of the maximum SOC and the minimum SOC; applying, by the processor, the deviation SOC to a first SOC upper limit and a first SOC lower limit corresponding to a battery operating range to calculate a second SOC upper limit and a second SOC lower limit; calculating, by the processor, a first weight of the maximum SOC and a second weight of the minimum SOC based on the second SOC upper limit, the second SOC lower limit, and the average SOC, and applying, by the processor, the first weight and the second weight to the maximum SOC and the minimum SOC to calculate the representative SOC of the battery rack.

In some embodiments, in calculation of the second SOC lower limit, the processor may subtract a preset ratio of the deviation SOC from the first SOC upper limit to calculate the second SOC upper limit and may add the preset ratio of the deviation SOC to the first SOC lower limit to calculate the second SOC lower limit.

In some embodiments, in calculation of the second weight, the processor may calculate the second weight by dividing a value obtained through subtraction of the average SOC from the second SOC upper limit by a value obtained through subtraction of the second SOC lower limit from the second SOC upper limit and may calculate the first weight by subtracting the second weight from 1.

A battery state-of-charge estimation apparatus and method according to an embodiment calculates a representative SOC of a battery rack based on a maximum SOC of a maximum-voltage cell and a minimum SOC of a minimum-voltage cell upon charging/discharging a battery rack including multiple cells, thereby providing an effect of protecting batteries from overcharging/overdischarging while enabling calculation of the SOC with minimal resources.

A battery state-of-charge estimation apparatus and method according to the present disclosure calculates a representative SOC of a battery rack based on a maximum SOC of a maximum-voltage cell and a minimum SOC of a minimum-voltage cell upon charging/discharging the battery rack including multiple cells, thereby providing an effect of protecting batteries from overcharging/overdischarging while enabling calculation of the SOC with minimal resources.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A battery state-of-charge estimation apparatus, comprising:
a memory; and
a processor connected to the memory,
wherein, upon charging/discharging a battery rack comprising multiple battery cells, the processor calculates a maximum state of charge (SOC) of a maximum-voltage cell and a minimum SOC of a minimum-voltage cell and calculates a representative SOC of the battery rack based on the maximum SOC and the minimum SOC.

2. The battery state-of-charge estimation apparatus as claimed in claim 1, wherein, upon charging/discharging the battery rack, the processor calculates the maximum SOC based on a voltage and current of the maximum-voltage cell having a highest voltage among voltages of the multiple battery cells, and calculates the minimum SOC based on a voltage and current of the minimum-voltage cell having a lowest voltage among the voltages of the multiple battery cells.

3. The battery state-of-charge estimation apparatus as claimed in claim 1, wherein the processor calculates a first weight of the maximum SOC and a second weight of the minimum SOC based on a battery operation range, an average SOC and a deviation SOC of the maximum SOC and the minimum SOC, and applies the first weight and the second weight to the maximum SOC and the minimum SOC, respectively, to calculate the representative SOC.

4. The battery state-of-charge estimation apparatus as claimed in claim 3, wherein the processor applies the deviation SOC to a first SOC upper limit and a first SOC lower limit corresponding to the battery operation range to calculate a second SOC upper limit and a second SOC lower limit, and calculates the first weight of the maximum SOC and the second weight of the minimum SOC based on the second SOC upper limit, the second SOC lower limit, and the average SOC.

5. The battery state-of-charge estimation apparatus as claimed in claim 4, wherein the processor subtracts a preset ratio of the deviation SOC from the first SOC upper limit to calculate the second SOC upper limit and adds the preset ratio of the deviation SOC to the first SOC lower limit to calculate the second SOC lower limit.

6. The battery state-of-charge estimation apparatus as claimed in claim 4, wherein the processor calculates the second weight by dividing a value obtained through subtraction of the average SOC from the second SOC upper limit by a value obtained through subtraction of the second SOC lower limit from the second SOC upper limit, and calculates the first weight by subtracting the second weight from 1.

7. A battery state-of-charge estimation method comprising, upon charging/discharging a battery rack comprising multiple battery cells:
receiving, by a processor, measurement data of each of the battery cells from a sensor;
calculating, by the processor, a maximum SOC of a maximum-voltage cell and a minimum SOC of a minimum-voltage cell based on the measurement data of each of the battery cells; and
calculating, by the processor, a representative SOC of the battery rack based on the maximum SOC and the minimum SOC.

8. The battery state-of-charge estimation method as claimed in claim 7, wherein, in calculating the maximum SOC of the maximum-voltage cell and the minimum SOC of the minimum-voltage cell, the processor calculates the maximum SOC based on a voltage and current of the maximum-voltage cell having a highest voltage among voltages of the multiple battery cells, and the minimum SOC based on a voltage and current of the minimum-voltage cell having a lowest voltage among the voltages of the multiple battery cells.

9. The battery state-of-charge estimation method as claimed in claim 7, wherein calculating a representative SOC of the battery rack includes:
calculating, by the processor, an average SOC and a deviation SOC of the maximum SOC and the minimum SOC;
applying, by the processor, the deviation SOC to a first SOC upper limit and a first SOC lower limit corresponding to a battery operating range to calculate a second SOC upper limit and a second SOC lower limit;
calculating, by the processor, a first weight of the maximum SOC and a second weight of the minimum SOC based on the second SOC upper limit, the second SOC lower limit, and the average SOC; and
applying, by the processor, the first weight and the second weight to the maximum SOC and the minimum SOC, respectively, to calculate the representative SOC of the battery rack.

10. The battery state-of-charge estimation method as claimed in claim 9, wherein, in calculating the second SOC lower limit, the processor subtracts a preset ratio of the deviation SOC from the first SOC upper limit to calculate the second SOC upper limit and adds the preset ratio of the deviation SOC to the first SOC lower limit to calculate the second SOC lower limit.

11. The battery state-of-charge estimation method as claimed in claim 9, wherein, in calculating the second weight, the processor divides a value obtained through subtraction of the average SOC from the second SOC upper limit by a value obtained through subtraction of the second SOC lower limit from the second SOC upper limit and calculates the first weight by subtracting the second weight from 1.
